(19) United States
(12) Patent Application Publication
(10) Pub. No.: US 2008/0195904 A1
(43) Pub. Date: Aug. 14, 2008

(54) Test Point Insertion and Scan Chain Reordering for Broadcast-Scan Based Compression

(75) Inventor: Seongmoon Wang, Plainsboro, NJ (US)

Correspondence Address: NEC LABORATORIES AMERICA, INC., 4 INDEPENDENCE WAY, Suite 200, PRINCETON, NJ, 08540, US

(73) Assignee: NEC LABORATORIES AMERICA, INC., Princeton, NJ (US)

(21) Appl. No.: 12/015,129

(22) Filed: Jan. 16, 2008

Related U.S. Application Data
(60) Provisional application No. 60/888,813, filed on Feb. 8, 2007.

(51) Int. Cl. G01R 31/3181; G06F 11/26

(52) U.S. Cl. 714/726; 714/E11.159

(57) ABSTRACT

A method for increasing fault coverage and compression with a broadcast scan-based test data compression circuit includes inserting test points for breaking correlations existing between scan inputs that belong to same scan slices making some faults un-testable with a broadcast scan-based test data compression circuit; and reordering scan inputs for further reducing correlations between scan inputs that belong to the same scan slices.

This application claims the benefit of U.S. Provisional Application No. 60/888,813, entitled “Design-for-Test Technique to Enhance Performance of Broadcast Scan-Based Compressor”, filed on Feb. 8, 2007, the contents of which is incorporated by reference herein.

### BACKGROUND OF THE INVENTION

The present invention relates generally to compression testing of large application specific integrated circuits, and more particularly, to enhancing performance of broadcast-scan based test compression by test point insertion and scan chain reordering techniques.

Due to ever increasing design size, the cost for testing large application specific integrated circuit (ASIC) designs have sky rocketed. Shrinking process parameters have further aggravated the testing problem because new types of defects such as crosstalk noise, small delay defects, etc., are manifested in the device. Now test engineers require new defect oriented fault models to detect these defects, which is fueling the test cost. With ever increasing demands for integrating large numbers of functionality into a single chip, it leaves little doubt that test cost is going to soar in the near future. Two factors governing the test cost are: a) test application time, and b) test volume. Since test application time directly affects the overall turn-around time of the design, it increases the unit cost of the chip. Test vectors are stored in the automatic test equipment (ATE) and are transferred to the core while testing. Since ATEs have limited memory, channel capacity, and bandwidth, large test volume can affect the overall test time, adding to the test cost.

One solution to this problem is to use built-in self test (BIST). BIST uses on-chip hardware to test the cores in the design and completely eliminates the need to use an ATE for giving test inputs and for comparing the output response. Several BIST schemes have been proposed, but are not widely used in the industry because of their inability to achieve the desired test quality. One BIST technique proposed encoding test data based on intelligent reseeding of single polynomial linear-feedback shift registers LFSRs. This technique offered reduced storage requirements and smaller area overhead compared to weighted random patterns. With s specified bits in a test vector, the LFSR should be s+20 bits long in order to reduce the probability of not finding a seed for a test cube to less than 10⁻⁶. Hence, for the designs with large number of scan flip-flops (SFFs), the LFSR hardware overhead becomes prohibitively expensive.

Recently, test compression techniques have been widely used for reducing test time. In this approach, a precomputed test set T_{D} for an IP core is compressed (encoded) to a much smaller test set, T_{E}, which is stored in the ATE memory. An on-chip decoder is used for pattern decompression to obtain T_{D} from T_{E} during test application. A few popular compression process recently presented in the literature include statistical coding, selective Huffman coding, and variable-to-variable-length Golomb coding. A disadvantage of the compression technique is that additional hardware is required to decode the test pattern.

The broadcast scan architecture is widely used in the industry to reduce test volume and the test application time. However, it introduces several undesired correlations among different signal lines in the circuit that severely affect the performance of both the test generation and the test compaction tools. Accordingly, there is a need for improved fault coverage and compression with broadcast scan architectures.

### SUMMARY OF THE INVENTION

In accordance with the invention, a method for increasing fault coverage and compression with a broadcast scan-based test data compression circuit includes inserting test points for breaking correlations existing between scan inputs that belong to same scan slices making some faults un-testable with a broadcast scan-based test data compression circuit; and reordering scan inputs for further reducing correlations between scan inputs that belong to the same scan slices. In the preferred embodiment, inserting the test points includes identifying scan groups that are defined as sets of scan chains that are driven by same scan chain inputs, and inserting the test points includes determining gain functions for all signal lines in the circuit for choosing places to insert the test points, the gain function reflecting the number of scan flip-flops in a scan group that should be specified to set a signal to a desired value and/or to propagate a fault at the signal line to outputs. In the preferred embodiment, the step of reordering scan inputs includes reordering neighboring scan flip-flops within distance restriction to maximize the overall gain value, the gain value reflecting overall reduction in the total number of scan flip-flops in scan slices that cause conflicts in the circuit due to reordering scan flip-flops, the step of reordering scan inputs includes determining scan flip-flop conflict and slice correlation for the circuit and the step of reordering scan inputs includes computing gain values for scan flip-flop pairs, the gain value reflecting overall reduction in slice conflicts in the circuit due to swapping of a given scan flip-flop pair.

### BRIEF DESCRIPTION OF DRAWINGS

These and other advantages of the invention will be apparent to those of ordinary skill in the art by reference to the following detailed description and the accompanying drawings.

FIG. 1 is a diagram of a broadcast scan architecture which can be improved by the method according to the invention.

FIG. 2A details the inventive test point insertion and scan-chain reordering steps for improving fault coverage and compression in broadcast scan-based compression.

FIG. 2B shows a design flow employing the test point insertion and scan-chain reordering steps in the design of a broadcast scan-based architecture.

FIG. 3 is a diagram illustrating correlated flip-flops.

FIG. 4 is a block diagram illustrating a complete test point.

FIG. 5 is a diagram showing an optimized complete test point.

FIG. 6 is a diagram showing the steps for identifying correlated flip-flops.

FIG. 7 is a diagram depicting the overall test point insertion steps in accordance with an aspect of the invention.

FIGS. 8a and 8b are diagrams illustrating untestable faults.

FIG. 9 is a diagram illustrating building neighborhood information, in accordance with an aspect of the invention.

FIG. 10 is a diagram showing updation steps in accordance with an aspect of the invention.

FIG. 11 is a diagram showing overall re-ordering steps in accordance with an aspect of the invention.

FIG. 12 is a table of results for inserting 60 test points illustrating the effectiveness of the invention.

### DETAILED DESCRIPTION

The invention includes a test-point-insertion TPI technique that can break broadcast scan architecture correlations among different signal lines in the circuit that severely affect the performance of both the test generation and the test compaction tools to make the design more amenable for test generation and test compaction. The invention includes a scan chain re-ordering technique that further reduces the correlations, which drastically reduces the test data volume and the test application tine. It uses the layout information and restricts the distance by which a particular scan flip-flop can be moved in the layout to minimize the scan chain routing overhead due to the proposed re-ordering operation. This also makes it more practical as any post-synthesis layout modification can be easily accommodated. The inventive TPI and scan chain re-ordering enables a design for-test scheme that can be integrated into any existing very large scale integrated VLSI design flow without impacting the overall design turn-around time.

As noted above, both the compression technique and BIST along with a LFSR re-seeding technique have several disadvantages. The broadcast scan architecture overcomes all of the disadvantages and offers a very good test volume compression, high test application time reduction and little hardware overhead. Since, it is also very easy to implement, it is widely used in the industry. A known Illinois Scan Architecture is an implementation of the broadcast scan concept and is also referred as Parallel/Serial Full Scan (PSFS) that will now be described in detail.

The Parallel/Serial Full Scan (PSFS) can be implemented by dividing the scan chain into multiple partitions and shifting the same vector to each scan chain through a single scan input. FIG. 1 shows the organization of flip-flops in the broadcast scan architecture 1. Flip-flops are partitioned into n scan chains and are labeled Scan Chain 1, 2 . . . n, respectively. The block labeled MISR represents an n-input multiple input shift register and is used for response compaction. The TE input controls the operation of the PSFS cores. When TE is 0, the core operates in the normal mode. When TE is 1, the core operates in the test mode. The operation of the broadcast scan in the test mode is controlled by the control flip-flop, CFF. When CFF=1, the core operates in the serial test mode. The operation of the broadcast scan core in the serial test mode is same as the operation of the full scan core in the test mode, i.e., the new values are shifted into each flip-flop serially through the SI input and the previous values of all flip-flops are shifted out serially through the SO output. When CFF=0, the broadcast scan core operates in parallel test mode. In the parallel test mode, shifting out test responses from all scan chains is done in parallel using the MISR. The MISR collects the bit streams coming out from n scan chains, compacts them and serially outputs the compacted response through SO output.

The advantage of the parallel mode is that a much shorter test sequence will now be shifted into the scan chain. This reduces both test volume and test application time. But note that the same bit is shifted into different scan chains, which reduces the testability of the core in parallel mode. Thus, the effectiveness of the technique also relies on the scan chain partitioning and ordering processes.

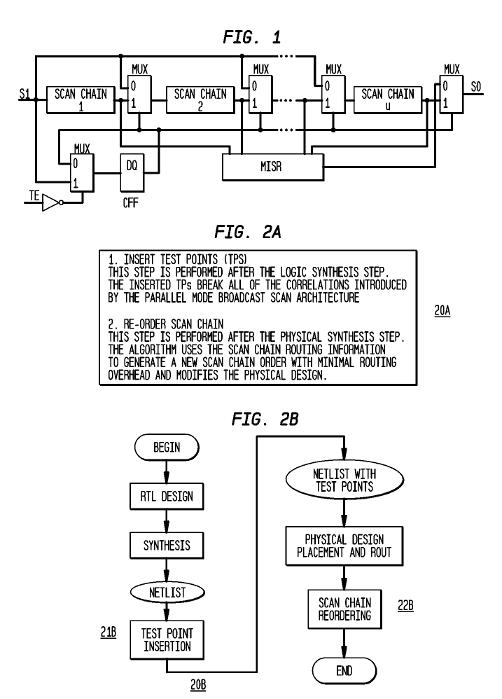

The invention is a two phase procedure, shown by diagram 20A in FIG. 2A, that improves broadcast scan-based compression. An exemplary design flow diagram 20B in FIG. 2B shows inclusion of the inventive test point insertion and scan chain reordering steps 21B, 22B in a complete design process. The design process begins with the RTL design, RTL mapping into a gate level netlist, the inventive test point insertion, ascertaining a netlist with test points, the physical design placement and route, and the scan chain reordering.

In the first phase, performed after a logic synthesis step, test points are inserted such that the resulting design is more amenable for the parallel mode of the broadcast scan test generation. The TPI process is described in greater detail below. In the second phase, we re-order the scan chain to further improve the testability of the design. The re-ordering step is done directly into the physical design by considering the existing placement and routing information. By restricting the distance by which a scan flip-flop SFF is moved, this step does not incur much routing overhead. The layout-aware scan chain re-ordering scheme is described in further detail below.

### I Test Point Insertion Procedure

As mentioned before, we insert test points after the logic synthesis step. The proposed TPI process does not require the scan chain ordering information because the exact scan ordering information is typically not available after the logic synthesis step. However, the process uses the design hierarchical information that is available after the logic synthesis step to partition the scan flip-flops SFFs such that the resulting partitions later translate to a particular scan chain after the physical design. It is assumed that the given design has several scan groups where a scan group means a group of scan chains SC₁, SC₂, SC₃ that derive the same test input bit from a single external scan-in pin Scan In as shown 30 in FIG. 3.

To understand the test point insertion (TPI) process, we define a new term called correlated flip flops using a parameter θ. Let CF₁ and CF₂ be sets of at least θ SFFs in two different scan chains SC₁ and SC₂ respectively in the same scan group satisfying the following condition: For every SFF ψ₁ ∈ CF₁ there exist a SFF ψ₂∈CF₂ such that ψ₁ and ψ₂ converge at some internal signal line and vice-versa. Then, all SFFs in the set CF₁ and CF₂ are correlated SFFs.

This is illustrated 30 in FIG. 3 that shows three scan chains SC₁, SC₂, and SC₃ in the same scan group. We assume θ=5. The → in the figure represents a path and the represents internal signal lines where the two paths converge. We see that six SFFs in SC₁ correlates with five SFFs in SC₂ (shaded SFFs in FIG. 3) and hence, there are 11 correlated SFFs. Correlated SFFs can generate several conflicting assignments during the parallel mode broadcast scan test pattern generation and, hence, they reduce the performance of the test pattern generation (TPG) and the test compaction tool. Further below, it will be shown how correlated SFFs can also cause several faults to become untestable even though they are testable in the serial mode.

The key idea of the proposed TPI process is to insert the test points (TPs) into the design such that the parallel mode broadcast scan test pattern generator TPG will now specify lesser number of these correlated SFFs to detect as many faults as possible. Hence, the inventive TPI scheme minimizes the number of times a correlated SFF will have to be specified during the parallel mode broadcast TPG to detect as many faults as possible in the design. This will reduce the number of conflicting assignments while also increasing the fault coverage during the parallel mode broadcast scan TPG. Hence, the inventive TPI process is significantly different from all other prior known TPI schemes, as it specifically improves the testability of designs employing broadcast scan architecture.

### I.1 The Test Point Hardware

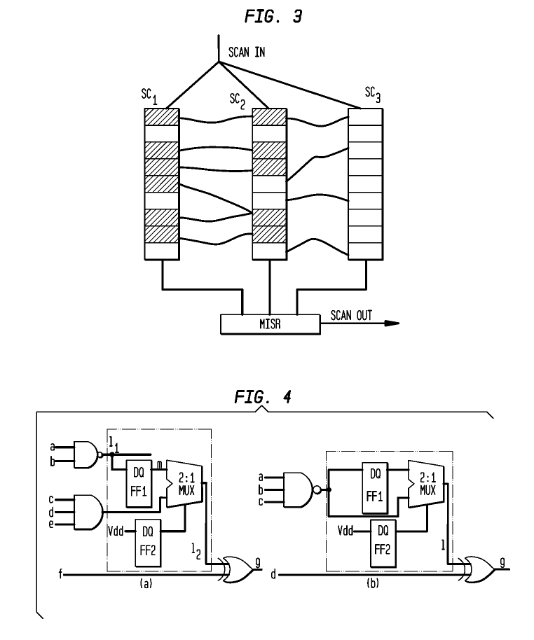

We will now describe how to implement a test point and the overhead associated with it. A complete test point (CTP) for structured ASICs that can observe a signal line l₁ while also controlling another line l₂ to Boolean 0/1, see diagram (a) in FIG. 4. The diagram (b) in FIG. 4 shows a CTP that can observe and control the same signal line l.

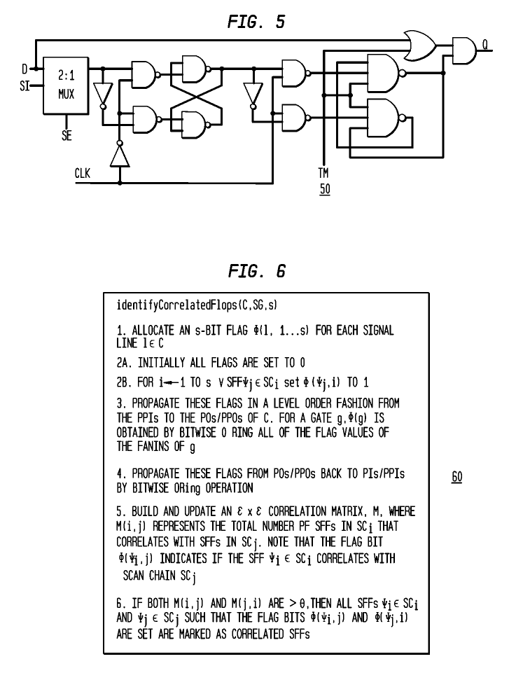

Note that two scan flops and a MUX is required to implement a complete test point CTP. In this work, we propose an optimized implementation of a CTP that controls and observes a signal line l. It is shown by diagram 50 in FIG. 5 and is implemented by modifying the SFF design and adding an OR-AND gate at the output. The input labeled TM represents the test mode signal. During the test mode, we can load the desired Boolean value 0/1 into the CTP through the scan chain. In this mode, the CTP observes the input D while also controlling the output Q to Boolean 0/1. During the functional mode, the test point behaves like a regular buffer. The delay added by this test point hardware during the functional mode is the delay of an OR-AND gate. Thus, this test point can be used only when the available slack in that path is greater than the OR-AND gate delay. When the available slack is very less, then one can insert an observation point (OP) to improve the testability. Since, the test point hardware is stitched with the other SFFs in the design through the scan chain, inserting a test point increases the pattern length by one.

### I.2 Identify Correlated Flip-Flops

The first step of the inventive TPI process is to identify all of the correlated SFFs in the design. The module identifyCorrelated Flops (C, SG, s) shown by the block 60 in FIG. 6 identifies all of the correlated SFFs in the given scan group SG. Here C is the circuit, s is the number of internal scan chains in SG, and SC₁, SC₂, . . . , SCs denote the s internal scan chains. Also, PI/PPI means primary/pseudo-primary input and PO/PPO means primary/pseudo-primary output. We use an s-bit flag in each signal line l for identifying the correlated SFFs and is denoted by φ(l). In the steps 1-2, we initialize Φ(l) for all the signal lines l ∈ C. In the steps 3-4, we propagate the flag values to identify all scan chains that drives all the internal signal lines. By propagating the flag bits back to the SFFs, we identify SFF correlation information. In the steps 5-6, we identify all of the correlated SFFs in SG. Note that the time and memory complexity of this process is O(n) where n is the total number of signals reachable from the SFFs in SG. This is because the step 3 and 4 visits each reachable signal line only once. The cost of steps 5 and 6 is O(s²), but note that s<<n. Also, the cost of steps 1 and 2 is O(|SG|) where |SG| represents the total number of SFFs in SG, which is <n. So the total complexity is 0(n+s²+|SG|)≈0(n).

After identifying all of the correlated SFFs in the design, we compute the gain functions for all of the signal lines to choose the best places to insert the TPs. To describe the gain function, let N_{OF}(l) represent the number of correlated SFFs that must be specified to observe l, N_{CF}¹l(N_{CF}⁰(l))represent the number of correlated SFFs that must be specified to control l to 1 (0), N_{f}(1) be the total number of independent faults that need to pass through l to be detected, F_{C}¹(l)(F_{C}⁰(l)) represent the number of independent faults that are excited due to inserting a control point (CP) at l and F_{C}¹(l)(F_{C}⁰(l)) represent the number of independent faults that pass through the AND/NANDIXOR/XNOR(OR/NOR/XOR/XNOR) gate g where l is an input of g. The gain function G_{CTP} for the complete test point is expressed as this theorem:

Theorem: The lower bound on the total number of times a correlated SFF need not be specified due to inserting a CTP at signal line l is:

G_{CTP}(l)=G_{CP}¹(l)+G_{CP}⁰(l)+G_{OP}(l) (1)

Where

G_{CP}^{v}(l)=(F_{C}^{v}(l)+F_{O}^{v}(l)×N_{CF}^{v}(l),v=0/1

G_{OP}(l)=N_{f(l)}×N_{OF(l)}

Proof. The ATPG tool has to generate at least F_{C}¹(l) vectors to excite the faults in the fanout of l and at least F_{O}¹(l) vectors to observe the faults in the fanin cone of the off-path signals of l (because all of the F_{C}¹(l)+F_{O}¹(l) faults are independent). When the CTP at 1 is used as a 1 (0)-CP, the correlated SFF bits in these vectors need not be specified by the ATPG. So, the gain due to this is G_{CP}⁰(l)+G_{CP}¹(l). Also, at least N_{OF}(l) vectors are needed to detect the faults in the fanin cone of l because N_{OF}(l) fault effects pass through l in the absence of this test point. When the CTP observes l, the correlated SFF bits in these vectors will not be specified by the ATPG. So, the gain due to this is G_{OP}(l). Also, by definition, there are no overlapping faults among G_{CP}¹(l), G_{CP}⁰(l) and G_{OP}(l). Hence, the sum G_{CP}¹(l)+G_{CP}⁰(l)+G_{OP}(l) is a lower bound on the total number of times correlated SFFs need not be specified due to inserting a CTP at signal line l.

We use a two pass process to compute the gain function represented by equation (1). In the first pass, we compute N_{f}(1), N_{OF}(l), N_{CF}^{v}(l), F_{O}^{v}(l) and F_{C}^{v}(l) for all circuit signal lines. In the next pass, we calculate the gain functions for all signal lines using equation (1). Since this is compution intensive, we approximate wherever necessary. We also present several optimizations to significantly reduce run time and memory usage of our test point insertion TPI tool.

### I.3 Controllability and Observability Cost

The controllability cost N_{CF}^{v}(l) (v=0/1) for a signal line l is the total number of the correlated SFF bits that need to be specified to set l to logic v. The observability cost N_{OF}(l) is the total number of the correlated SFF bits that need to be specified to propagate the fault effect at l to a PO/PPO. If the design has reconvergent fanouts, then calculating accurate controllability and observability for signal l is difficult. As a simple estimation, we can use a measure where the observability cost of the line li is obtained by simple additions of controllability costs of all its other inputs and the observability cost of l_{O} where signal line li is the i^{th} input of gate g and l_{O} is g's output. This is defined as:

### if li is a PO/PPO

$$O ( {l}_{i )} = \{ \begin{matrix}0 , & if {l}_{i} is PO / PPO \\ {\sum }_{j \neq i} {C}_{\overline{c}} ( {l}_{j} ) + O ( {l}_{o} ) , & otherwise\end{matrix} \qquad ( 2 )$$

Where c_{c}−(lⱼ) reflects the number of correlated SFFs required to set the line lj to its non-controlling Boolean value c̅. The controllability cost Cᵥ(lᵢ) of signal line lᵢ that is driven by gate g reflects the number of correlated SFFs to be specified to set line lᵢ to Boolean value v defined as:

$${C}_{v} ( {l}_{i} ) = \{ \begin{matrix}1 , & if {l}_{i} is correlated \\ {\sum }_{∀ {l}_{j} ∈ Fanin ( g )} {C}_{\overline{c}} ( {l}_{j} ) , & if v = \overline{c} ⊕ inv \\ {min}_{∀ {l}_{j} ∈ Fanin ( g )} \{ {C}_{c} ( {l}_{j} ) \} , & otherwise\end{matrix} \qquad ( 3 )$$

Where ⊕ represents Boolean XOR operator, Fanin(g) represents the fanin of gate g and inv represents the Boolean inversion parity of gate g (Boolean 0 for AND/OR/BUF gates and Boolean 1 for NAND/NOR/NOT gates). However, a type of measure described in Equations 2 and 3 is fairly inaccurate due to the presence of reconvergent signals. Hence, we use bit arrays to represent controllability and observability of signal lines, which can improve the accuracy of the controllability/observability calculations.

We use three bit arrays, denoted CC_{O}(l), CCₗ(l ) and O(l), for each signal line l to store the 1-, the 0-controllabilities and the observabilities, respectively. The j^{th} entry of the controllability arrays of line l tells whether the j^{th} PI/PPI in that circuit cone controls l or not. Similarly, the j^{th} entry of the observability array, O(^{l}), tells whether the j^{th} PI/PPI needs to be specified or not to observe l at the PO/PPO of the circuit cone.

A disadvantage of using a bitmap is that it requires a large memory space to store intermediate bit operation results. To reduce memory, we partition the design into a large number of circuit cones Ci, i=1, 2, . . . A particular cone Ci comprises one PO/PPO, denoted p, and all signal lines located in the transitive fanin of p. Memory allocated for computing the testability measures (N_{CF}^{v}(l) and N_{OF}(l)) of all signal lines in Ci is freed before considering the next circuit cone. This approach drastically reduces the peak run time memory consumed by our TPI tool.

A two-pass process computes testability values of all lines l in the cone Ci. All the bit arrays (CC_{O}, CCₗ and O) of all signal lines l in Cᵢ are initialized to 0's. In the first pass, we traverse from PIs/PPIs in level order toward the PO/PPO of cone Ci, computing both CC1(1) and CCo(1) for each signal line l. Since a 1 in the bit array CC₁(l) (CCo(l)) means that particular PI/PPI must be specified to set l to 1 (0), counting the number of 1's in CC₁(1), (CCo(1)) that correspond to the correlated SFF gives the value of N_{CF}¹(l) (N_{CF}⁰(l)). In the second pass, we traverse from the PO/PPO of Ci toward PIs/PPIs. In this pass, we compute the bit array O(1) for observing the fault effect at each signal line l at the PO/PPO of this cone. N_{OF}(l) for signal line l is the number of 1's in the bit array that corresponds to the correlated SFF. Next, we describe procedures to compute N_{f}, F_{c}^{v}(l) and F_{O}^{v}(l) for all circuit signal lines. Since this computation is not memory intensive, the procedure does not use partitioning.

I.4 Computing N_{f}f(l), F_{c}^{v}(l) and F_{O}^{v}(l)

As mentioned earlier, N_{f}(l) is defined as the total number of independent faults that need to pass through l to be detected, F_{c}^{v}(l) is the total number of independent faults that are excited when a v-CP, where v=0/1 , at signal line l is switched on. Testability measure F_{O}^{v}(l) is the total number of independent faults that pass through all off-path signals of l by setting l to logic value v. Computing N_{f}(l), F_{c}^{v}(l) and F_{O}^{v}(l) involves counting the number of independent faults but identifying independent faults in a circuit is very computation intensive. So, we approximate the total number of independent faults by the total number of collapsed faults and is described next.

### I.4.1 Fault Collapsing

We present an process to compute a highly collapsed fault set, FSₘ, for the circuit. The process begins with an initial collapsed fault set FSₒ comprising all circuit stuck-at 0 and stuck-at 1 faults. Initially, the size of FS₀ is 2×n, where n is the number of signal lines in the circuit. Starting from the PIs/PPIs, we consider a fault f ∈ FS₀ and remove all the faults ff from the set FS₀ that are equivalent to f or dominated by f to get a reduced fault set FS₁. Two faults f and fc are said to be equivalent if every pattern that detects f also detects fc and vice-versa. Fault f dominates fc if every pattern that detects f, also detects fc. We continue reducing the fault set FSj, where j=0, 1, 2, . . . , m until we cannot reduce it further.

### I.4.2 Computing Nf(l)

After obtaining the collapsed fault list, we then compute N_{f}(l), F_{c}^{v}(l) and F_{O}^{v}(l) for all signal lines l. All N_{f}(l) values are initially zeroed. The process propagates each fault f guided by the observability cost, Ni, toward a PO/PPO. When a fault effect propagates through line l, N_{f}(l) is incremented. When all faults are propagated, we obtain N_{f} values for all circuit signal lines.

### I.4.3 Computing F_{c}^{v}(l) and F_{O}^{v}(l)

We compute f_{c}^{v}(l) and F_{O}^{v}(l) from the N_{f}(l) values. We first initialize all F_{c}^{v}(l) values in the circuit to 0. Then, we assign a logic value v to l and imply the Boolean value to as many signal lines as possible that are located in the transitive fanout of 1. When a Boolean value v_{f} propagates to line l_{f}, such that the fault stuck-at v̅f̅ at l_{f} belongs to the final collapsed fault list FSₘ., then F_{c}^{v}(l) is incremented. When this operation is performed for all circuit signal lines, we obtain F_{c}^{v}(l) values for the entire circuit. To compute F_{O}^{v}(l), the process identifies the list of all gates G_{f} such that: (a)l is a fanin of G_{f} and (b) v is a non-controlling value of G_{f}. Then, it obtains all fanin signals Fᵢₙ, of all gates G_{f} excluding 1, so Σ_{f}_{ᵢₙ} _{∈ F}_{ᵢₙ}N_{f}(fᵢₙ) represents F_{O}^{v}(l).

### I.5 Updating Testability Measures

Once a CTP is inserted into line l, the gain values for all lines in the neighborhood of l are updated to reflect the extra CTP that has been added. We first identify all lines Lin in the fanin cone of l such that a fault effect from lᵢₙ ∈ Lᵢₙ passes through I before reaching a PO/PPO before inserting a CTP. We then subtract the value of N_{f}(l) from N_{f}(lᵢₙ) because the fault effect at lin will now be observed at l itself. We then obtain all signal lines Lout in the fanout cone of l such that fault effects from l pass through lₒᵤₜ ∈ Lₒᵤₜ before reaching a POIPPO before inserting a CTP. Since N_{f}(l) faults will now be observed at l, we subtract the value of N_{f}(l) from N_{f}(Lₒᵤₜ) to update the N_{f} values.

Also, inserting CIP at l decreases the controllability of l and all signals in the transitive fanout of l. To update gain values of other lines, we obtain the set of all lines L_{DI} that are directly implied by setting l to logic v. We then obtain the list of all output signals I_{DI}^{out} ∈ L_{DI}^{out} such that: (a) l_{DI}^{out} ∉ L_{DI}^{out} and (b) l_{DI}^{out} and is a fanout signal of some l_{DI} ∈ L_{DI}. Thus, the entire set of signals lₐₗₗ ∈ L_{DI} ∪ L_{DI}^{out} represent signal lines that directly benefit from inserting a CTP at 1. Then, we decrement the value N_{CF}^{v}(l) from the controllability values of all signal lines lₐₗₗ ∈ L_{DI} ∪ L_{DI}^{out}. This completes the procedures for updating testability measures after inserting a particular test point TP.

### I.6 The Overall TPI Process

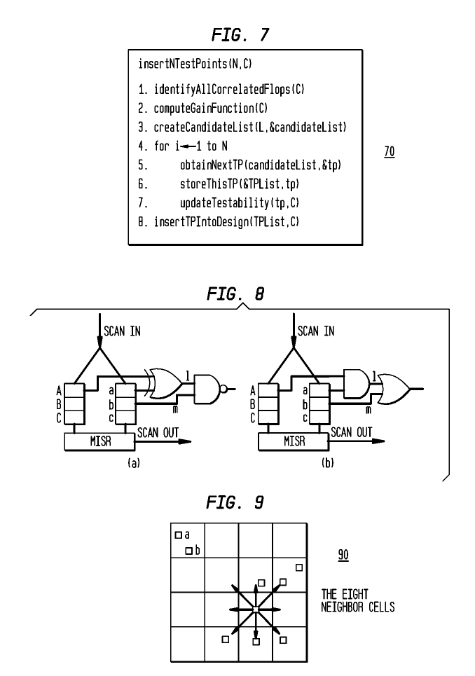

The block 70 of FIG. 7 shows the overall process to insert N TPs into the design C. The procedure identifyAllCorrelatedFlops( ) uses the process described in Section I.2 above to identify all correlated SFFs in C. The procedure computeGainFunction( ) computes the. Gain function for all signal lines in the circuit. The procedure createCandidateTestPoints( ) creates a list comprising L signals with highest gain values. This list represents the search space of the inventive test point insertion TPI tool. Since searching only L signals for TPI purposes is less expensive than evaluating all circuit signals, this step greatly reduces the total run time of our TPI tool. In this application, L=10×N. Procedure obtainNextTP( ) gets a signal line with the highest gain function from the candidate list. Procedure storeThisTP( ) stores the chosen signal line in a list and is later used by insertTPlntoDesign( ), which writes the design along with all inserted test points TPs back onto the disk. Procedure updateTestability( ) updates the value of testability measures of all signal lines in the candidate list due to inserting the chosen test point TP (see I.5 above).

### II Scan Chain Re-Ordering Technique

A near optimal scan ordering scheme for the broadcast scan architecture has been proposed by others. But implementing that optimal scan ordering may change the existing placement and routing, thereby, adding extra turn-around time into the design flow. To overcome this, we restrict the distance by which a SFF can be moved in the physical design. The restriction reduces the routing overhead due to the scan re-ordering process, while also making it more practical to be used after the physical synthesis step.

Due to the correlation that exists among different scan flip-flops SFFs, several faults remain untestable in the parallel mode broadcast scan architecture. We call them artificially untestable faults and classify them into three groups:
1. Artificially Uncontrollable faults are those for which the excitation condition is not met due to the broadcast scan constraints. The fault l sa 0 in FIG. 8(a) is an artificially uncontrollable fault because it is not possible to set l=1.
2. Artificially Unobservable faults are untestable faults for which the observability condition is not met. The fault m sa 1 in FIG. 8(a) is an artificially unobservable fault because line m is always unobservable in the parallel broadcast scan mode.
3. Artificially Undrivable faults are those for which it is possible to independently excite and/or observe the fault effect at on of the PO/PPO but simultaneously exciting and observing the fault results in a conflict. The fault l sa 0 in FIG. 8(b) is an artificially undrivable fault. We can set A=0 to observe l and also a=1, b=1 to excite the fault but the assignment A=O, a=1, b=1 results in a conflict.

These untestable faults can be made testable by re-ordering the SFFs. For e.g., swapping SFF A and B in the above designs converts all of the untestable faults into testable faults due to the following reason: SFFs A and a will always take the same Boolean value due to the broadcast scan architecture. Swapping SFF A and B breaks this relationship making all faults testable. This example also sets the background for the proposed scan chain re-ordering process, which will be described shortly. But first, we will define a few terms that will used in the rest of this section.
1. Scan Slice, denoted by σ, is a set of SFFs in the same scan group that has to take the same bits from the scan-in pin (see FIG. 8(a)).
2. Conflicting SFF Pair. The SFF pair (ψ₁, ψ₂) is said to be conflicting if they have to take different values to detect one or more faults in the design.
3. SFF Conflict represents the total number of times a SFF pair (ψ₁, ψ₂) have to take to detect all faults in the design and is denoted by κ(ψ₁,ψ₂)
4. Slice Correlation, S(ψ,σ), of a SFF ψ with respect to the scan slice σ represents the total number of times ψ conflicts with each of the SFF ψ_{σ}. In FIG. 8(b), S(A,σ₂) is 1.
5. Slice Conflict represents the total number of times one or more pairs of SFF in σ conflicts to detect all of the faults in the design.

The key idea of the inventive scan re-ordering process is that a SFF pair (ψ₁ ∈ σ₁ ∈ σ₂) will be swapped only if. a) ψ₁ lies in the neighborhood of ψ₂, and b) swapping minimizes the slice conflicts of σ1 or σ2 or both. Hence, the scan re-ordering process uses the existing scan ordering to convert as many artificially untestable faults into testable faults.

### II.1 Build Neighborhood Information

The first step of the scan re-ordering process is to build a neighborhood list denoted by ψ₁.NList for each SFF ψ in the design. For the purpose of this research, we use the netlist to decide if SFFs ψ₁, and ψ₂ are separated by a distance <r (r is a user defined parameter). Building the neighborhood list for all SFFs in the design will require us to compute the distance between every SFF pair using the layout file, which will cost O(N²_{SFF}) where N_{SFF} is the total number of SFFs in the design. This is prohibitively expensive especially when N_{SFF} is very large. So, we propose an approximate and an inexpensive process for this.

First, map the layout onto an imaginary two dimensional grid of size P×Q as shown by the blovk 90 in FIG. 9 where the choice of P, Q determines the accuracy of the process. Only the SFF placement is shown in the figure and P=4, Q=4 for the purpose of illustration. Build a 2D matrix data structure G of size P×Q such that G(i, j) stores the list of SFFs in the (j, j) cell. For the layout given in FIG. 9, G(1, 1) will store SFFs a and b where as G(1, 2) will be NULL. Now, to obtain the neighbor of any SFF located inside any grid G(x, y), we can include all SFFs located at the eight neighboring cells of G(x, y). The total cost of this process is only 8×N_{SFF}+P×Q≈O(NSFF) if we choose P, Q such that the product P×Q is linearly proportional to NSFF.

### II.2 Slice Correlation

To compute the slice correlation, we reuse the bitmap CC0, CC1, and CO described in Section 4.3. Recall that CC0(l) (CC1(l)) represents the PIs/PPIs that need to be specified to obtain Boolean 0(1) at line l and CO(l) represents the bitmap to observe l. Then, the bit array S0(l)=OR(CC1(l), CO(l)) will represent the set of PIs/PPIs that need to be specified to detect the 1sa0 fault because we need to control signal line l to 1 and also observe l at some PO/PPO. Similarly, S1(l)=OR(CC0(l), CO(l)) will represent the set of PIs/PPIs that need to be specified to detect 1 sal. We compute S0(l) and SI(l) for all of the signal lines in the design. Using these bitmaps, we directly compute both SFF conflict and the slice correlation for the entire design.

### II.3 Computing the Gain Value

We compute gain values for SFF pairs (ψ₁,ψ₂) such that ψ₁ is located in the neighborhood of, ψ₂(distance<r). The gain value reflects the overall reduction in the slice conflicts in the entire design due to the swapping of that SFF pair and is given using the theorem below:

Theorem: Let ψ₁ ∈ σ₁ be a SFF located in the neighborhood of ψ₂ ∈ σ₂. The gain due to swapping the SFF pair (ψ₁,ψ₂), denoted by G_{RO} (ψ₁,ψ₂) is:

$${G}_{RO} ( {ψ}_{1} , {ψ}_{2} ) = S ( {ψ}_{1} , {σ}_{1} ) + S ( {ψ}_{2} , {σ}_{2} ) - S ( {ψ}_{1} , {σ}_{2} ) - S ( {ψ}_{2} , {σ}_{1} )$$

Proof: The total number of slice conflicts that are reduced due to removing ψ₁ from σ₁ and ψ₂ from σ₂ is S(ψ₁,σ₁)+S(ψ₂,σ₂). However, moving the SFF ψ₁ into σ₂ and ψ₂ into σ₁ introduce slice conflicts, which is S(ψ₁,σ₂)−S(ψ₂,σ₁). Hence, the total gain is G_{RO}(ψ₁,ψ₂)=S(ψ₁,σ₁)+S(ψ₂,σ₂)−S(ψ₁, σ₂)−S(ψ₂,σ₁). This completes the proof.

### II.4 Updating Gain Values

Each time when a SFF pair (ψ₁,ψ₂) is swapped, the slice correlation value will completely change. Since, re-computing the gain values for all candidate pairs can be very expensive, we only update the gain values of the neighbors of ψ₁ and ψ₂ that is expressed as a theorem:

Theorem: Let ψ₁ ∈ σ₁ be a SFF located in the neighborhood of ψ₂ ∈ σ₂. The change in the slice correlation value, ΔS(ψ,σ₁,), of the SFF ψ located in the neighborhood of ψ₁ due to the swapping of the SFF pair (ψ₁,ψ₂) is:

ΔS(ψ,σ₁)=κ(ψ,ψ₁)−κ(ψ,ψ₂) (4)

Proof: The total number of SFF conflicts that are reduced due to removing ψ₁ from σ₁ is κ(ψ,ψ₁). However, moving the SFF ψ₁ into σ₂ introduces SFF conflicts, which is κ(ψ, ψ₂). Hence, the total reduction in slice correlation is ΔS(ψ,σ₁)=κ(ψ,ψ₁)−κ(ψ,ψ₂). Similarly, we can say that ΔS(ψ,σ₂)=κ(ψ,ψ₂)−κ(ψ,ψ₁). This completes the proof.

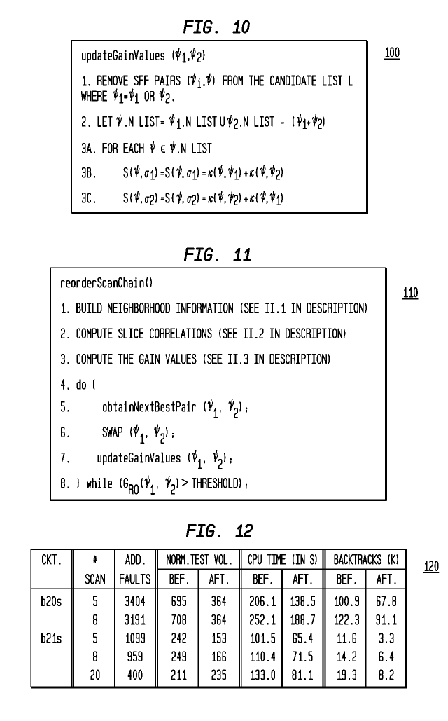

The process for updating the gain values for the entire design due to the swapping of SFF pair (ψ₁,ψ₂) is given by the block 100 in FIG. 10. The first step prevents the process from moving a particular SFF multiple times. In the second step, we collect all of the neighbors of ψ₁ and ψ₂ and use the above Theorem in steps 3a-c for updating their slice correlation values.

### II.5 The Overall Process

The overall process for layout-aware scan chain re-ordering is given by the block 110 in FIG. 11. The first step builds the neighborhood information and also constructs the candidate SFF pair list. The second step computes both the SFF conflict values and the slice correlation values. The SFF correlation values are later used in step 7 for updation. In step 3, gain values are computed using the slice correlation values. The scan re-ordering is an iterative process and is implemented by steps 4-8. The method obtainNextBestPairO will obtain the SFF pair in the candidate list that has the highest gain value. This pair is then swapped in step 6 and in step 7, we update the gain values as described in Section II.4. This process stops when the maximum gain value of the candidate SFF pairs falls below certain threshold value.

### III Results

The entire tool was implemented in the C programming language and an in-house test pattern generation tool was used for our experiments. Extensive experiments were conducted with ISCAS '89, ITC '99 and industrial benchmark circuits (ckt1, ckt2) to validate the efficacy of the proposed design for test DFT technique. In the first round of experiments, we evaluated the efficacy of the test point insertion TPI step. We inserted 60 test points into different scan configurations of b20s and b21s. The results are shown in Table 120 of FIG. 12. The column labeled Add. faults represents the additional number of faults detected in the parallel mode due the TPI step. The column labeled Norm. Test Vol. represents the normalized test volume. The column CPU Tune (ins) represents the total CPU time required for the test generation step. The column labeled Backtracks (K) represents the total number of backtracks for achieving a near 100% fault efficiency. From the results, we see that the TPI step alone helps reduce test volume for broadcast scan architecture by up to 49%. Results on scan chain re-ordering indicate that another 5% reduction in test volume can be achieved.

The invention described herein permits a new design-for-test scheme comprising test point insertion and layout aware scan chain re-ordering method to enhance the performance of a broadcast scan-based compressor for testing integrated circuits. Broadcast scan architecture is widely used in the industry to reduce test volume and the test application time. However, it introduces several undesired correlations among different signal lines in the circuit that severely affect the performance of both the test generation and the test compaction tools. The invention includes a test point insertion TPI technique that can break these correlations to make the design more amenable for test generation and test compaction. Results indicate that the TPI step alone can help a broadcast scan compressor by up to 49% further reduction in test volume. The inventive technique also employs a scan chain re-ordering that further reduces the correlation and hence, drastically reduces the test data volume and the test application time. It uses the layout information and restricts the distance by which a particular scan flip-flop can be moved in the layout to minimize the scan chain routing overhead due to the proposed re-ordering operation. The proposed scan re-ordering step can obtain another 5% reduction in test volume for the broadcast scan-based compressors.

In summary, the invention employs a test point insertion step and a scan-chain reordering to improve broadcast scan compression testing of ASICs. The inventive technique provides the following advantages:

Little turn-around time overhead. Since the inventive technique is divided into two procedures, it can be seamlessly integrated with any VLSI design flow without resulting in any extra iteration of any of the VLSI design flow steps. Also, the time complexity of the proposed inventive process is 0(n) where n is the number of signal lines in the design. Thus, the invention does not affect the overall turn-around time of the design cycle.

Little timing overhead. We use the results of the static timing analysis to identify all of the signal lines in the design that does not lie in the timing critical paths and insert test points only on these signal lines. Hence, our technique does not affect the overall timing of the design.

Little routing overhead. During the scan chain re-ordering step, we restrict the maximum distance by which any SFF is moved in the physical design. We do this by using the placement and routing information of the design. Hence, our technique incurs very little routing overhead.

Ease of post-synthesis layout modifications. In a typical VLSI design cycle, designers incorporate several modifications (e.g., last minute bug fixes) late in the design cycle into the physical design. This adds extra turn-around time as one will have to iterate the entire design for test DFT and timing verification procedures to accommodate these modifications. From the DFT viewpoint, the proposed layout-aware re-ordering scheme is very useful in this scenario because it can directly modify the physical design without incurring much timing overhead while quickly converging to the routing closure.

The present invention has been shown and described in what are considered to be the most practical and preferred embodiments. It is anticipated, however, that departures may be made therefrom and that obvious modifications will be implemented by those skilled in the art. It will be appreciated that those skilled in the art will be able to devise numerous arrangements and variations which, although not explicitly shown or described herein, embody the principles of the invention and are within their spirit and scope.

What is claimed is:

1. A method for increasing fault coverage and compression with a broadcast scan-based test data compression circuit, comprising the steps of:
inserting test points for breaking correlations existing between scan inputs that belong to same scan slices making some faults un-testable with a broadcast scan-based test data compression circuit; and
reordering scan inputs for further reducing correlations between scan inputs that belong to the same scan slices.

2. The method of claim 1, wherein the step of inserting test points comprises identifying scan groups that are defined as sets of scan chains that are driven by same scan chain inputs.

3. The method of claim 1, wherein the step of inserting test points comprises determining gain functions for all signal lines in the circuit for choosing places to insert the test points, the gain function reflecting the number of scan flip-flops in a scan group that should be specified to set a signal to a desired value and/or to propagate a fault at the signal line to outputs.

4. The method of claim 3, wherein the step of inserting test points comprises inserting test points to selected signal lines with highest gain values.

5. The method of claim 6, wherein step of inserting test points comprises updating gain values of all signal lines due to inserting a chosen test point.

6. The method of claim 1,wherein the step of reordering scan inputs comprises building neighborhood information for all scan flip-flops in the circuit.

7. The method of claim 1, wherein the step of reordering scan inputs comprises identifying correlated scan flip-flops in each scan slice that cause conflicts during test generation.

8. The method of claim 1, wherein the step of reordering scan inputs comprises reordering neighboring scan flip-flops within distance restriction to maximize the overall gain value, the gain value reflecting overall reduction in the total number of scan flip-flops in scan slices that cause conflicts in the circuit due to reordering scan flip-flops.

9. The method of claim 1, wherein the step of reordering scan inputs comprises determining scan flip-flop conflict and slice correlation for the circuit.

10. The method of claim 1, wherein the step of reordering scan inputs comprises computing gain values for scan flip-flop pairs, the gain value reflecting overall reduction in slice conflicts in the circuit due to swapping of a given scan flip-flop pair.

11. The method of claim 1, wherein the step of reordering scan inputs comprises an iterative process of 1) obtaining a scan flip-flop pair having a highest gain value reflecting overall reduction in slice conflicts in the circuit due to swapping of a given scan flip-flop pair, 2) swapping the scan flip-flop pair having the highest gain value, and 3) updating gain values for all scan-flops due to the prior swapping scan flip-flop pair.

12. The method of claim 11, wherein the step of reordering scan inputs comprises repeating steps 1) to 3) until a maximum gain value of scan flip-flop pairs falls below a certain threshold.
